(19) United States
(12) Patent Application Publication
(10) Pub. No.: US 2010/0078820 A1
(43) Pub. Date: Apr. 1, 2010

(54) SEMICONDUCTOR DEVICE AND METHOD OF MANUFACTURING THE SAME

(75) Inventors: TETSUYA KUROKAWA, KANAGAWA (JP); MAKOTO TOHARA, KANAGAWA (JP)

Correspondence Address: YOUNG & THOMPSON, 209 Madison Street, Suite 500, Alexandria, VA, 22314, US

(73) Assignee: NEC ELECTRONICS CORPORATION, KANAGAWA (JP)

(21) Appl. No.: 12/569,936

(22) Filed: Sep. 30, 2009

(30) Foreign Application Priority Data
Sep. 30, 2008 (JP) 2008-252455

(51) Int. Cl. H01L 23/532; H01L 21/768

(52) U.S. Cl. 257/751; 438/643; 257/E23.161; 257/E21.584

(57) ABSTRACT

A metal barrier film which contains an additive element is formed on the side face and on the bottom of a trench formed in an insulating film; a seed film is formed over the metal barrier film; a plated layer (Cu film) is formed using the seed film as a seed so as to fill up the trench with a metal film; the metal barrier film and the metal film are annealed to thereby form therebetween an alloy layer which contains a metal composing the metal barrier film, the additive element, and a metal composing the metal film, and to thereby allow the additive element to diffuse into the metal film.

This application is based on Japanese patent application No. 2008-252455 the content of which is incorporated hereinto by reference.

### BACKGROUND

1. Technical Field

The present invention relates to a semiconductor device which has an interconnect buried in an insulating film, and a method of manufacturing the same.

2. Related Art

There has been known an interconnect structure of semiconductor devices, configured to fill up a trench, which is formed in an insulating film, with an electro-conductive layer (Cu layer, for example). In thus-configured interconnect, there is provided a barrier film (diffusion preventive film) between the interconnect and the insulating film, aimed at preventing a metal composing the electro-conductive layer from diffusing into the insulating film. Provision of the barrier film raises a need of ensuring adhesiveness between the interconnect and the barrier film. On the other hand, the interconnect is in need of addition of an impurity, for the purpose of improving resistance against electomigration.

Japanese Laid-Open Patent Publication No. 11-204524 discloses use of a TiN/Ti film as a diffusion preventive film. The publication also discloses that a Cu film is formed by plating on a Ag-containing seed film, and Ag contained in the seed film is then allowed to diffuse into the Cu film by annealing. According to the method described in Japanese Laid-Open Patent Publication No. 11-204524, an interconnect reportedly excellent in electro-conductivity and resistance against electromigration may be obtained. Japanese Laid-Open Patent Publication NO. 2006-73792 discloses use of a Ta, W, TaN, WSiN or TiN film as a diffusion preventive film. The publication also discloses that a Cu film is formed by plating on a Ti—Al alloy seed film. According to the method described in the Japanese Laid-Open Patent Publication No. 2006-73792, an metal interconnect reportedly excellent in adhesiveness between the cu film and the diffusion preventive film and resistance against Stress-Induced voiding (SIV).

Japanese Laid-Open Patent Publication No. 2004-047846 discloses a method of forming a metal interconnect, which includes the processes below. First, a metal seed layer and a metal material layer are formed over an impurity-containing barrier layer, and then annealed at a first temperature capable of allowing thereunder growth of crystal grains to proceed in the metal material layer and the metal seed layer. The impurity-containing barrier layer, the metal seed layer, and the metal material layer are then removed in the portions thereof which lie over an insulating film, to thereby form a metal interconnect. The product is then annealed at a second temperature higher than the first temperature, capable of allowing thereunder diffusion of an additive element contained in the impurity-containing barrier layer into the metal interconnect. In Japanese Laid-Open Patent Publication No. 2004-047846, the impurity-containing barrier layer is a nitride layer typically composed of TaMgN, TaN, TaCN, TaSiN or the like. According to the method of forming a metal interconnect described in Japanese Laid-Open Patent Publication No. 2004-047846, a metal interconnect reportedly excellent in the adhesiveness and resistance against electromigration may be formed. In Japanese Laid-Open Patent Publication No, 2001-93976, a barrier layer is a titanium nitride layer on titanum (TiN/Tior) or a tantalum nitride on a tantlum (TaN/Ta) and an alloy layer is formed between the barrier and metal interlayer. According to the method of forming a metal interconnect described in Japanese Laid-Open Patent Publication No. 2001-93976, a metal interconnect reportedly excellent in the adhesiveness, electroconductivity may be formed.

Japanese Laid-Open Patent Publication Nos. 2006-80234, 2005-150690 and 2005-317804 disclose methods by which a metal layer is provided between a barrier film and a seed film, and a metal composing the metal layer is allowed to diffuse into an interconnect by annealing.

In recent years, the seed layer has been becoming thinner with progress of shrinkage of semiconductor devices. Accordingly, for an exemplary case where the interconnect is formed by plating, electric resistance of the seed layer may be causative of difference in the amount of plating current between the center and periphery of a wafer, and may consequently result in difference in the thickness of a plated film between the center and periphery of the wafer.

In the method described in Japanese Laid-Open Patent Publication Nos. 11-204524 and 2006-73792, the seed layer has a large electric resistance due to the impurity added thereto, so that the above-described problem becomes more distinctive. On the contrary, the method described in Japanese Laid-Open Patent Publication No. 2004-047846 is not causative of increase in the electric resistance of the seed layer, because the impurity is added to the barrier film, and is consequently successful in suppressing in-plane variation in the thickness of the plated film over the wafer. However, the impurity is less diffusible from the barrier film to the metal interconnect, because a nitride film is used as the barrier film, and thereby the adhesiveness between the metal interconnect and the barrier film, and resistance of the interconnect against electromigration may degrade. Further, in the method described in Japanese Laid-Open Patent NO. 2001-93976 an impurity also is less diffusible from the barrier film to the metal interconnect, because a nitride film TiN or TaN is respectively used between the barrier film Ti or Ta and the metal interconnect. According to the method of forming a metal interconnect described in Japanese Laid-Open Patent NO. 2001-93976, the impurity is less diffusible from the barrier film Ti or Ta to the metal interconnect, because a nitride film TiN or TaN is respectively used between the barrier film and the metal interconnect. The adhesiveness between the metal interconnect and the barrier film and resistance of the interconnect against electromigration may degrade. Each of the methods described in Japanese Laid-Open Patent Publication Nos. 2006-080234, 2005-150690 and 2005-317804 need formation of the extra metal film between the barrier metal film and the interconnect, and consequently needs increased manhour.

It has, therefore, been desired to develop a technique which is capable of suppressing difference in the thickness of a plated film between the center and the periphery of the wafer, while suppressing degradation in the adhesiveness between the interconnect and the barrier film, degradation in the resistance against electromigration, and increase in manhour.

### SUMMARY OF THE INVENTION

According to the present invention, there is provided a method of manufacturing a semiconductor device, which includes forming a trench in an insulating film provided over a semiconductor substrate; forming a metal barrier film which contains an additive element, on the side face and on the bottom of the trench formed in the insulating film; filling up the trench with a metal film by forming a seed film over the metal barrier film, and further by forming a plated film using the seed film as a seed; forming, by annealing the metal barrier film and the metal film, an alloy layer which includes a metal composing the metal barrier film, the additive element, and a metal composing the metal film, between the metal barrier film and the metal film, and allowing the additive element to diffuse into the metal film.

In the present invention, a metal barrier film is used as the barrier film. Therefore, the additive element added to the metal barrier film may thoroughly be diffused into the metal film. Accordingly, the resistance of the metal film against electromigration may be improved. Since the alloy layer is formed between the metal barrier film and the metal film, the adhesiveness between the metal film and the metal barrier film may be improved. Since the additive element is added to the metal barrier film, so that any extra step of adding an additive element is no more necessary, and thereby the manhour may be prevented from increasing. Since the impurity is added to the metal barrier film, so that the seed layer is suppressed from increasing in the electric resistance, and the thickness of the plated film is consequently suppressed from varying between the center and periphery of the wafer.

According to the present invention, there is provided also a semiconductor device which includes an insulating film provided over a semiconductor substrate; a trench formed in said insulating film; a metal barrier film formed on the side face and on the bottom of said trench; a metal interconnect formed over said metal barrier film so as to fill up said trench; and an alloy layer formed between said metal barrier film and said metal interconnect, wherein said metal barrier film contains an additive element alloyable with a metal composing said metal interconnect, said metal interconnect contains said additive element, and said alloy layer contains a metal composing said metal barrier film, said additive element, and a metal composing said metal interconnect.

According to the present invention, the thickness of the plated film is consequently suppressed from varying between the center and periphery of the wafer, while suppressing degradation in the adhesiveness between the interconnect and the barrier film, degradation in the resistance against electromigration resistance, and increase in manhour.

### BRIEF DESCRIPTION OF THE DRAWINGS

The above and other objects, advantages and features of the present invention will be more apparent from the following description of certain preferred embodiments taken in conjunction with the accompanying drawings, in which:

FIGS. 1A to 2B are sectional views explaining a method of manufacturing a semiconductor device according to a first embodiment;

FIGS. 3A and 3B are sectional views explaining a method of manufacturing a semiconductor device according to a second embodiment; and

FIGS. 4A to 5 are sectional views explaining a method of manufacturing a semiconductor device according to a third embodiment.

### DETAILED DESCRIPTION

The invention will now be described herein with reference to an illustrative embodiment. Those skilled in the art will recognize that many alternative embodiments can be accomplished using the teachings of the present invention and that the invention is not limited to the embodiments illustrated for explanatory purposes.

Embodiments of the present invention will be described below, referring to the attached drawings. Note that any similar constituents in all drawings will be given with similar reference numerals or symbols, and explanations therefor will not be repeated.

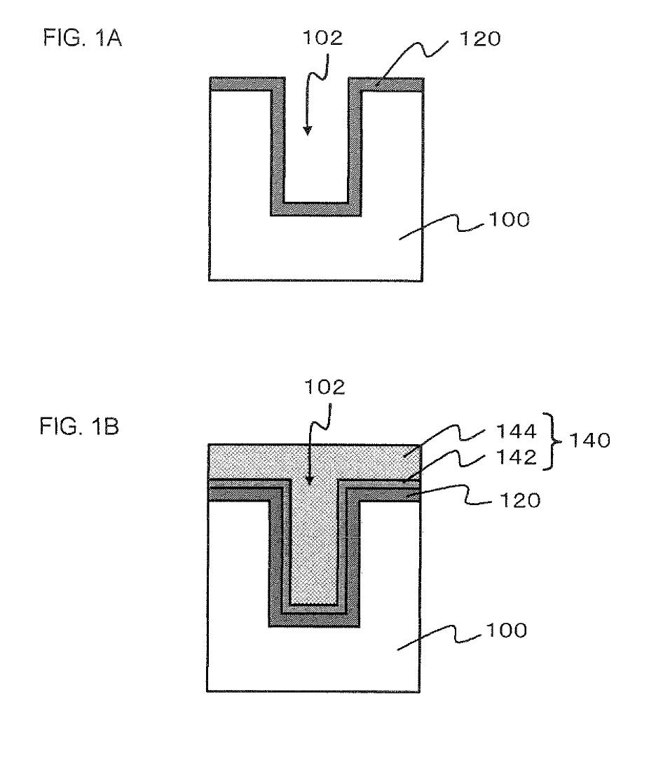

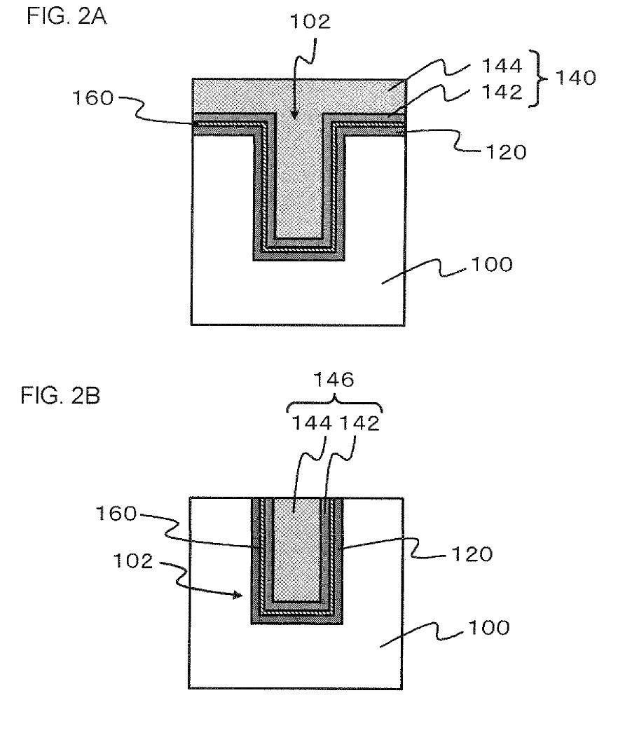

FIGS. 1A, 1B, 2A and 2B are sectional views explaining method of manufacturing a semiconductor device according to a first embodiment. The method of manufacturing a semiconductor device has steps described below. First, a trench 102 is formed in an insulating film 100 formed over a semiconductor substrate (not illustrated). Next, a metal barrier film 120 containing an additive element is formed on the side face and on the bottom of the trench 102 formed in the insulating film 100. Next, a seed film 142 is formed over the metal barrier film 120, and a plated layer (Cu film 144) is further formed using the seed film 142 as a seed, to thereby fill up the trench 102 with a metal film 140. The metal barrier film 120 and the metal film 140 are then annealed, to thereby form therebetween an alloy layer 160 which contains a metal composing the metal barrier film 120, the additive element, and a metal composing the metal film 140, and to thereby allow the additive element to diffuse into the metal film 140. Detailed description will be given below.

First, as illustrated in FIG. 1A, the trench 102 is formed in the insulating film 100 provided over the semiconductor substrate (not illustrated). Next, the metal barrier film 120 is formed over the insulating film, and on the bottom and on the side face of the trench 102, typically by sputtering. The metal barrier film 120 has a thickness of equal to or more than 1 nm and equal to or less than 20 nm, for example, and contains an additive element. The metal composing the metal barrier film is typically Ti, and the additive element is typically Al. Note that the metal composing the metal barrier film 120 may alternatively be Ta, Zr, Hf, Ru, Ti—Ta, Ru—Ti, Ru—Ta, Ni, Co or W. The additive element may alternatively be at least one element selected from the group consisting of Mg, Mn, Fe, Zn, Zr, Nb, Mo, Ru, Pd, Ag, In, Ti, Sn, Au, Pt, lanthanide-series metal, and actinide-series metal. The concentration of the additive element in the metal barrier film 120 is typically equal to or more than 0.1% by weight and equal to or lass than 50% by weight.

Next, as illustrated in FIG. 1B, the seed film 142 is formed by sputtering over the metal barrier film 120. The seed film 142 is typically composed of a Cu film. The seed film 142 herein may, or may not contain any of the above-described additive element. For the case where the seed film 142 contain any additive element, the concentration of the additive element in the seed film 142 is preferably adjusted higher than 0% by weight and equal to or less than 0.3% by weight.

Next, electro-plating is conducted using the seed film 142 as a seed, to thereby form the Cu film 144 as the plated film. In this way, the metal film 140 which is composed of the seed film 142 and the Cu film 144 is formed in the trench 102. The metal film 140 herein is formed over the metal barrier film 120 also in the portion thereof which lies over the insulating film 100.

Next, as illustrated in FIG. 2A, the metal film 140 and the metal barrier film 120 are annealed. The temperature of annealing in this process is adjusted typically to equal to or more than 200° C. and equal to or less than 400° C., and preferably equal to or more than 250° C. and equal to or less than 350° C. Of course, the temperature of equal to or more than 350° C. and equal to or less than 400° C. is allowable. The duration of annealing is adjusted typically to 30 seconds to 1 hour. By the annealing, the additive element contained in the metal barrier film 120 diffuses into the metal interconnect, and at the same time, the alloy layer 160 which contains the metal composing the metal barrier film 120, the additive element, and the metal composing the seed film 142, is formed between the metal barrier film 120 and the seed film 142 of the metal film 140.

Next, as illustrated in FIG. 2B, the metal barrier film 120, the alloy layer 160, and the metal film 140 are removed in the portions thereof which lie over the insulating film 100, by CMP (Chemical Mechanical Polishing). Thus the trench 102 is filled up with a metal interconnect 146.

Although the portions of the metal barrier film 120, the alloy layer 160 and the metal film 140, which lie over the insulating film 100, were removed in the above-described embodiment after the alloy layer 160 was formed, the annealing for forming the alloy layer 160 may alternatively be preceded by removal of the metal barrier film 120 and the metal film 140 by CMP.

The semiconductor device formed as described in the above has, as illustrated in FIG. 2B, the insulating film 100 formed over the semiconductor substrate (not illustrated), the trench 102 formed in the insulating film 100, the metal barrier film 120 formed on the side face and on the bottom of the trench 102, and the metal interconnect 146 formed over the metal barrier film 120 and so as to fill up the trench 102. The metal barrier film 120 contains the additive element (Al, for example) alloyable with the metal (Cu, for example) composing the metal interconnect 146, and the metal interconnect 146 contains the above-described additive element. Between the metal barrier film 120 and the metal interconnect 146, the alloy layer 160 is positioned. The alloy layer 160 contains the metal composing the metal barrier film 120, the above-described additive element, and the metal composing the metal interconnect 146.

If the seed film 142 contains no additive element, the concentration profile of the additive element in the direction of stacking may have a peak in the metal barrier film 120. In this case, the concentration of the additive element in the metal interconnect 146 decreases in the direction departing from the metal barrier film 120. On the other hand, if the seed film 142 contains any additive element, the concentration profile of the additive element in the direction of stacking may have peaks respectively in the metal barrier film 120 and in the metal interconnect. In this case, the concentration of the additive element in the metal interconnect 146 decreases in the direction departing from the metal barrier film 120, at least in the plated layer 144.

Operations and effect of the present invention will now be explained. First, since the seed film 142 is not necessarily added with any additive element, or is optionally added to adjust the concentration thereof only to as low as equal to or less than 0.3% by weight, so that the resistivity of the seed film 142 may be adjustable to a low level as small as equal to or less 5 μΩcm. As a consequence, the Cu film 144, formed by electro-plating using the seed film 142 as a seed, may be suppressed from causing in-plane distribution of the thickness of the Cu film 144.

In addition, since the additive element contained in the metal barrier film 120 diffuses into the metal interconnect 146, so that the resistance of the metal barrier film 120 against electromigration may be improved. Since the alloy layer 160 is formed between the metal barrier film 120 and the metal interconnect 146, the adhesiveness between the metal interconnect 146 and the metal barrier film 120 may be improved. In particular in this embodiment, improvement in the adhesiveness may be distinctive, since the alloy layer 260 is formed almost over the entire portions of the bottom and side face of the metal interconnect 146. Since the additive element is added to the metal barrier film 120, any extra step of adding an additive element is no more necessary, and thereby the manhour may be prevented from increasing.

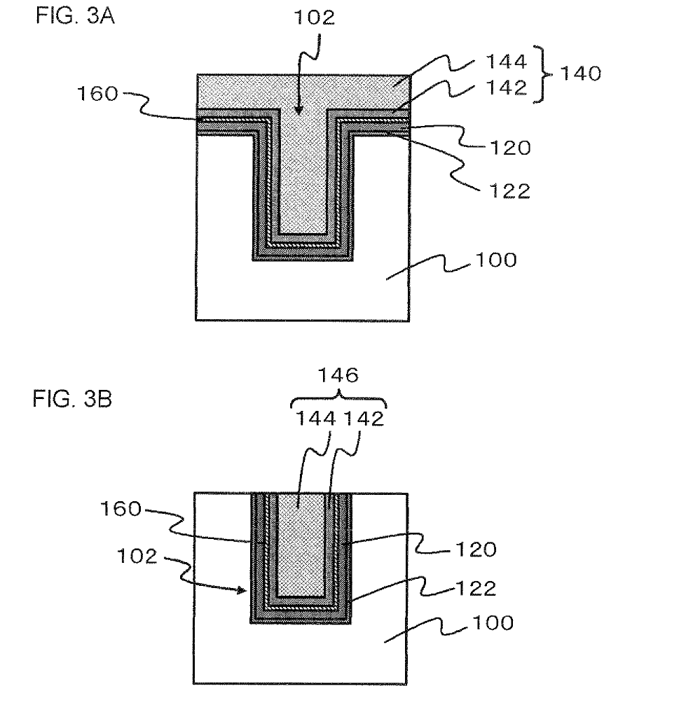

FIGS. 3A and 3B are sectional views explaining method of manufacturing a semiconductor device according to a second embodiment. FIG. 3A is a drawing correspondent to FIG. 2A in the first embodiment, and FIG. 3B is a drawing correspondent to FIG. 2B in the first embodiment. This embodiment is similar to the first embodiment, except that a second barrier film 122, which is a nitride film, is provided between the metal barrier film 120 and the insulating film 100.

More specifically, in this embodiment, a second barrier film 122 and the metal barrier film 120 are formed in this order, over the insulating film 100. The steps thereafter are similar to those explained in the first embodiment, except that also the second barrier film 122 is removed in the process of removing the metal barrier film 120, the alloy layer 160 and the metal film 140 in the portions thereof which lie over the insulating film 100. The second barrier film 122 is typically a film of nitride of the metal composing the metal barrier film 120. For an exemplary case where the metal barrier film 120 is a Ti film, the second barrier film 122 may be a TiN film or a TiSiN film. For another exemplary case where the metal barrier film 120 is a Ta film, the second barrier film 122 may be a TaN film. For still another exemplary case where the metal barrier film 120 is a W film, the second barrier film 122 may be a WN film.

Effects similar to those in the first embodiment may be obtained also in this embodiment. By virtue of provision of the second barrier film 122, composed of a nitride film, provided under the metal barrier film 120, the metal composing the metal interconnect 146 becomes more unlikely to diffuse into the insulating film 100.

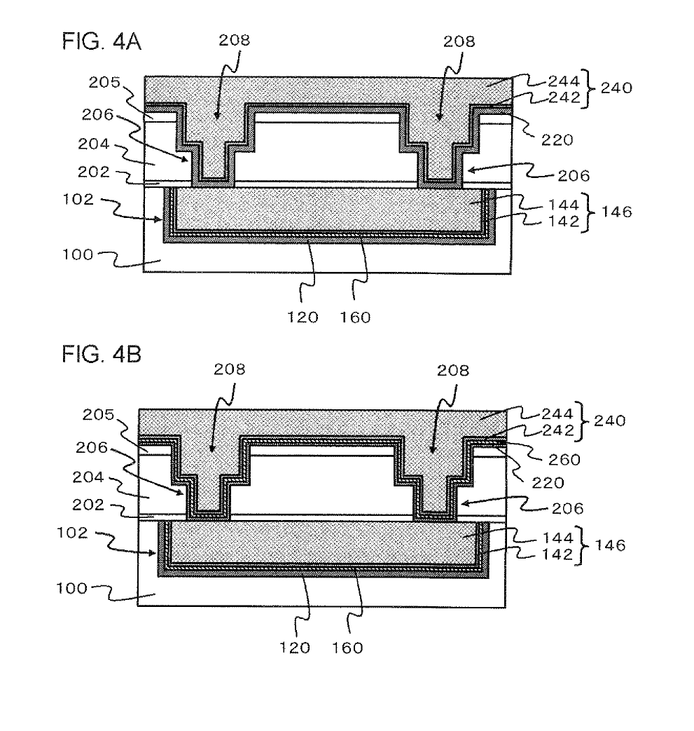

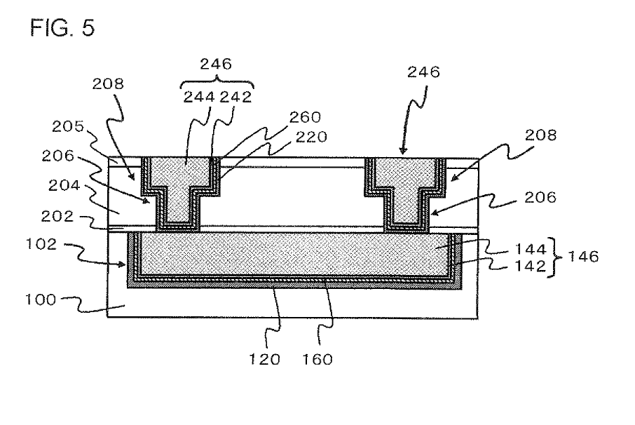

FIGS. 4A, 4B and FIG. 5 are sectional views explaining a method of manufacturing a semiconductor device according to a third embodiment. The method of manufacturing a semiconductor device is such as forming a second metal interconnect 246, over the metal interconnect 146 formed by the method of manufacturing a semiconductor device explained in the first or second embodiment FIGS. 4A, 4B and FIG. 5 illustrate the metal interconnect 146 formed by the method explained in the first embodiment.

First, the trench 102 formed in the insulating film 100 is filled with the metal interconnect 146 according to the method explained in the first embodiment or the second embodiment. Next, a diffusion preventive film 202 and an interlayer insulating film 204 are formed in this order over the insulating film 100 and the metal interconnect 146. The diffusion preventive film 202 is formed typically using SiCN, SiC, or SiN. The interlayer insulating film 204 may be configured by a low-k film having a dielectric constant of equal to or less than 3.3, and more preferably equal to or less than 2.9. The interlayer insulating film 204 may be configured typically by a film which contains Si, O and C. More specifically, the interlayer insulating film 204 may be configured typically by SiOC (SiOCH), methyl silsesquioxane (MSQ), hydrogenated methyl silsesquioxane (MHSQ), organic polysiloxane, and any of these films converted to have a porous structure.

Next, a protective insulating film 205 is formed over the interlayer insulating film 204. The protective insulating film 205 may be configured typically by SiO₂. Interconnect trenches 208 and viaholes 206 are then formed in the interlayer insulating film 204 and the protective insulating film 205. The viaholes 206 are located at the bottom of the interconnect trenches 208, so as to allow therein connection to the metal interconnect 146. Procedures for forming the interconnect trenches 208 and viaholes 206 may be either of the single damascene process and dual damascene process. Any known type of the dual damascene process, including the viahole-first process, trench-first process, middle-first process and dual-hard-mask process, may be adoptable.

Next, a metal barrier film 220 is formed on the bottoms and on the side faces of the interconnect trenches 208 and the viaholes 206. The composition of the metal barrier film 220 may be same with that of the metal barrier film 120. A seed film 242 is then formed over the metal barrier film 220, and electro-plating is conducted using the seed film 242 as a seed, to thereby form the a Cu film 244 as the plated layer. In this way, the interconnect trenches 208 and the viaholes 206 are filled up with a metal film 240 which is composed of the seed film 242 and the Cu film 244.

Next, as illustrated in FIG. 4B, the metal barrier film 220 and the metal film 240 are annealed. As a consequence, the alloy layer 260 is formed between the metal barrier film 220 and the metal film 240, and the additive element diffuses into the metal film 240. The alloy layer 260 contains a metal composing the metal barrier film 220, the additive element, and a metal composing the metal film 240.

Next, as illustrated in FIG. 5, the metal barrier film 220, the alloy layer 260 and the metal film 240 are removed in the portions thereof which lie over the insulating film 205, by CMP. In this way, the trenches 208 and the viaholes 206 are filled up with the metal interconnects 246. Each metal interconnect 246 is connected through the viahole 206 to the metal interconnect 146.

Effects similar to those in the first embodiment may be obtained also in this embodiment, in the process of forming the metal interconnects 246. It is now necessary that the adhesiveness between the metal interconnects 246 and the metal barrier film 220 is improved over the entire portion of the bottoms and side faces of the metal interconnects 246, since electrons migrate from the metal interconnect 146 towards the via holes 206 when electric current flows from the viahole 206 towards the metal interconnect 146. In this embodiment, the adhesiveness may be improved over the entire portion of the bottoms and side faces of the metal interconnects 246, by virtue of the alloy layer 260 formed over the entire portion of the bottoms and side faces of the metal interconnects 246.

The embodiments of the present invention have been described referring to the attached drawings. Note that the embodiments are given only for the purpose of exemplification, and allow adoption of any other various configurations.

It is apparent that the present invention is not limited to the above embodiment, but may be modified and changed without departing from the scope and spirit of the invention.

What is claimed is:

1. A method of manufacturing a semiconductor device comprising:
forming a trench in an insulating film provided over a semiconductor substrate;
forming a metal barrier film which contains an additive element, on the side face and on the bottom of said trench formed in said insulating film;
filling up said trench with a metal film by forming a seed film over said metal barrier film, and further by forming a plated film using said seed film as a seed;
forming, by annealing said metal barrier film and said metal film, an alloy layer which includes a metal composing said metal barrier film, said additive element, and a metal composing said metal film, between said metal barrier film and said metal film, and allowing said additive element to diffuse into said metal film.

2. The method of manufacturing a semiconductor device as claimed in claim 1,
wherein in said forming said seed film, said seed film is allowed to contain said additive element.

3. The method of manufacturing a semiconductor device as claimed in claim 2,
wherein the concentration of said additive element in said seed film is higher than 0% by weight and equal to or less than 0.3% by weight.

4. The method of manufacturing a semiconductor device as claimed in claim 2,
wherein said seed film has a resistivity of equal to or less than 5 μΩcm.

5. The method of manufacturing a semiconductor device as clamed in claim 1,
wherein the concentration of said additive element in said metal barrier film is equal to or more than 0.1% by weight and equal to or less than 50% by weight.

6. The method of manufacturing a semiconductor device as claimed in claim 1,
wherein in said forming said metal barrier film, said metal barrier film is formed also over said insulating film,
in said filling up said trench with said metal film, said metal film is formed also over said metal barrier film in the portion of said metal barrier film which lies over said insulating film, and
the method further comprising, after said forming said alloy layer, removing said metal film and said metal barrier film in the portions of said metal barrier film which lie over said insulating film.

7. The method of manufacturing a semiconductor device as claimed in claim 1,
wherein said metal barrier film contains at least one metal selected from the group consisting of Ti, Ta, Zr, Hf, Ru, Ti—Ta, Ru—Ti, Ru—Ta, Ni, Co, and W.

8. The method of manufacturing a semiconductor device as claimed in claim 1,
wherein said additive element is at least one element selected from the group consisting of Al, Mg, Mn, Fe, Zn, Zr, Nb, Mo, Ru, Pd, Ag, In, Ti, Sn, Au, Pt, lanthanide-series metal, and actinide-series metal.

9. A semiconductor device comprising:
an insulating film provided over a semiconductor substrate;
a trench formed in said insulating film;
a metal barrier film formed on the side face and on the bottom of said trench;
a metal interconnect formed over said metal barrier film so as to fill up said trench; and
an alloy layer formed between said metal barrier film and said metal interconnect,
wherein said metal barrier film contains an additive element alloyable with a metal composing said metal interconnect,
said metal interconnect contains said additive element, and
said alloy layer contains a metal composing said metal barrier film, said additive element, and a metal composing said metal interconnect.

10. The semiconductor device as claimed in claim 9,
wherein a concentration profile of said additive element in the direction of stacking has a peak in said metal barrier film.

11. The semiconductor device as claimed in claim 10,
wherein the concentration profile of said additive element in the direction of stacking has a peak also in said metal interconnect.

12. The semiconductor device as claimed in claim 9,
wherein the concentration of said additive element in said metal interconnect decreases in the direction departing from said metal barrier film.

13. The semiconductor device as claimed in claim 9,
wherein said metal barrier film contains at least one metal selected from the group consisting of Ti, Ta, Zr, Hf, Ru, Ti—Ta, Ru—Ta, Ru—Ti, Ni, Co, and W.

14. The semiconductor device as claimed in claim 9,
wherein said additive element is at least one element selected from the group consisting of Al, Mg, Mn, Fe, Zn, Zr, Nb, Mo, Ru, Pd, Ag, In, Ti, Sn, Au, Pt, lanthanide-series metal, and actinide-series metal.

15. The semiconductor device as claimed in claim 9,
wherein said metal interconnect is a copper interconnect,
said metal barrier film is a Ti film, and
said additive element is Al.

16. The semiconductor device as claimed in claim 9, further comprising a second barrier film which is composed of a nitride film, between said metal barrier film and said insulating film.
